(19) United States
(12) Patent Application Publication
(10) Pub. No.: US 2007/0228010 A1
(43) Pub. Date: Oct. 4, 2007

(54) Systems and methods for removing/containing wafer edge defects post liner deposition

(75) Inventors: James Scott Martin, Garland, TX (US); Kelly Jay Taylor, Allen, TX (US); Changfeng Xia, Plano, TX (US); Donald Wilson Culp, Plano, TX (US); David Chester Frystak, Frisco, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 11/395,799

(22) Filed: Mar. 31, 2006

(51) Int. Cl. B44C 1/22; B32B 1/08; H01L 21/306

(52) U.S. Cl. 216/83; 216/96; 216/99; 216/10; 156/345.11

(57) ABSTRACT

A method removes and/or contains edge residue. A wafer comprised of a semiconductor material having a top surface, a bottom surface and an edge surface is provided. The bottom surface and the top surface are substantially planar and the edge surface is non-planar. Residue can be located on the edge surface, which can dislodge if not addressed and damage devices formed on the wafer. One or more devices can be at least partially formed on the top surface. A pre-metal dielectric liner is formed over the top surface of the wafer and covering at least a portion of the residue. An edge portion of the liner is etched or otherwise removed to expose the portion of the residue. Thereafter, a pre-metal dielectric layer is formed over the top surface of the wafer and the pre-metal dielectric liner. During formation of the pre-metal dielectric layer, the edge residue is removed and/or contained.

### FIELD OF INVENTION

The present invention relates generally to semiconductor devices and more particularly to methods and systems for removing or containing wafer edge residue and defects resulting there from.

### BACKGROUND OF THE INVENTION

Semiconductor devices are formed on semiconductor wafers by performing a number of fabrication processes. For example, layers are formed by depositing materials, layers are patterned by employing etch processes, trenches are formed in substrates and filled with material, surfaces of the devices are planarized and cleaned, and the like.

As a result of these fabrication processes, residues and defects, including debris and contaminants, can be left on semiconductor wafers. For example, polishing/planarizing processes are typically employed to planarize layers deposited on the wafer. The polishing processes employ a chemical mechanical slurry and pad that mechanically and chemically planarize the wafer surfaces. After polishing, slurry residue is generally cleaned or scrubbed from wafer surfaces by mechanical scrubbing devices, such as polyvinyl acetate (PVA) brushes. These conventional cleaning processes tend to remove a substantial portion of the slurry residue, but some particles can remain as residue, particularly on edges of the wafer.

Another source of residue is due to metal film deposition. A clamp ring may be employed to secure a wafer to a heated pedestal within a deposition chamber to shield wafer edges from film disposition, such as to prevent metal from depositing along wafer edges and shorting subsequently formed devices as a result. Because the wafer and clamp ring possess different coefficients of thermal expansion, each expands at a different rate during metal film deposition. The shear force between the clamp ring and the wafer's edge may also generate edge particles that serve as a residue source.

Yet another source of residue is due to mechanical abrasion from wafer handling. Wafer holding/transporting mechanisms such as cassettes can deposit residue onto wafers. Such mechanisms can be employed during fabrication processes, for transporting wafers to and from machines, for transporting to an from chambers, and the like. In particular, some of the mechanisms come in contact with wafer edges and can deposit residue along edge surfaces of the wafers.

Patterning operations are another potential source of residue or defects. Patterning processes employ photoresist masks that can leave ashed resist as contamination or residue afterwards. Additionally, deposited materials, including metals and non-metals, can undesireably deposit on wafer edges as residue. Still other contaminants can be formed on the wafer edges from doping or ion implantation processes.

These residues can be sources of defects in later formed semiconductor structures. For example, layers can be formed on the residues or contaminants leading to blistering, delamination, undesired voids, and the like.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to the more detailed description that is presented later.

The invention facilitates semiconductor device fabrication by mitigating damage resulting from edge residue during fabrication. Aspects of the invention remove and/or contain the edge residue in order to prevent the edge residue from relocating from edge surfaces of a wafer to other portions of the wafer where the edge residue can degrade or prevent operation of devices formed therein.

Aspects of the invention control the edge residue by removing an edge portion of a liner layer. The edge residue is thus exposed and can be evaporated and/or contained by subsequent processing and subsequently formed layers. As a result, damage to devices formed on the wafer from the edge residue is mitigated.

In accordance with one aspect of the invention, a method is provided that removes and/or contains wafer edge residue. A wafer comprised of a semiconductor material having a top surface, a bottom surface and an edge surface is provided. The bottom surface and the top surface are substantially planar. The edge surface is non-planar and residue is located on the edge surface. A liner, such as a silicon nitride based liner, is formed over the top surface of the wafer and covering at least a portion of the residue. An edge portion of the liner is then removed to expose the portion of the residue. Subsequent processing can remove the residue and/or contain or prevent relocation of the residue to other portions of the top surface.

In accordance with an aspect of the invention, another method for containing or removing residue is provided. A wafer comprised of a semiconductor material having a top surface, a bottom surface and an edge surface is provided. The bottom surface and the top surface are substantially planar and the edge surface is non-planar. Residue can be located on the edge surface, which can dislodge if not addressed and damage devices formed on the wafer. A pre-metal dielectric liner is formed over the top surface of the wafer and covering at least a portion of the residue. An edge portion of the liner is etched or otherwise removed to expose the portion of the residue. Thereafter, a pre-metal dielectric layer is formed over the top surface of the wafer and the pre-metal dielectric liner. During formation of the pre-metal dielectric layer, the edge residue is removed and/or contained. Other methods and systems are disclosed.

To the accomplishment of the foregoing and related ends, the following description and annexed drawings set forth in detail certain illustrative aspects and implementations of the invention. These are indicative of but a few of the various ways in which the principles of the invention may be employed. Other aspects, advantages and novel features of the invention will become apparent from the following detailed description of the invention when considered in conjunction with the drawings.

### BRIEF DESCRIPTION OF THE DRAWINGS

FIG. 1 is a perspective view of an exemplary semiconductor wafer with edge residue.

FIG. 2 is a perspective view of another exemplary semiconductor wafer wherein edge residue has been removed.

FIG. 3A is a cross sectional view of a wafer at an edge surface in accordance with an aspect of the invention FIG. 3B is another cross sectional view of a wafer in accordance with an aspect of the invention.

FIG. 3C is yet another cross sectional view of a wafer in accordance with an aspect of the invention.

FIG. 4 is a flow diagram illustrating a method of fabricating a semiconductor device wherein edge residue is removed and/or contained in accordance with an aspect of the invention.

FIG. 5 is a block diagram illustrating a system for removing and/or containing wafer edge residue in accordance with an aspect of the present invention.

FIG. 6 is a view illustrating a solution dispenser within a system that directs a solution toward a bottom surface of a wafer in accordance with an aspect of the present invention is provided.

### DETAILED DESCRIPTION OF THE INVENTION

One or more implementations of the present invention will now be described with reference to the attached drawings, wherein like reference numerals are used to refer to like elements throughout, and wherein the illustrated structures are not necessarily drawn to scale.

The invention facilitates semiconductor device fabrication by mitigating damage resulting from edge residue during fabrication. Aspects of the invention remove and/or contain the edge residue in order to prevent the edge residue from relocating from edge surfaces of a wafer to other portions of the wafer where the edge residue can degrade or prevent operation of devices formed therein.

Aspects of the invention control the edge residue by removing an edge portion of a liner layer. The edge residue is thus exposed and can be evaporated and/or contained by subsequent processing and subsequently formed layers. As a result, damage to devices formed on the wafer from the edge residue is mitigated.

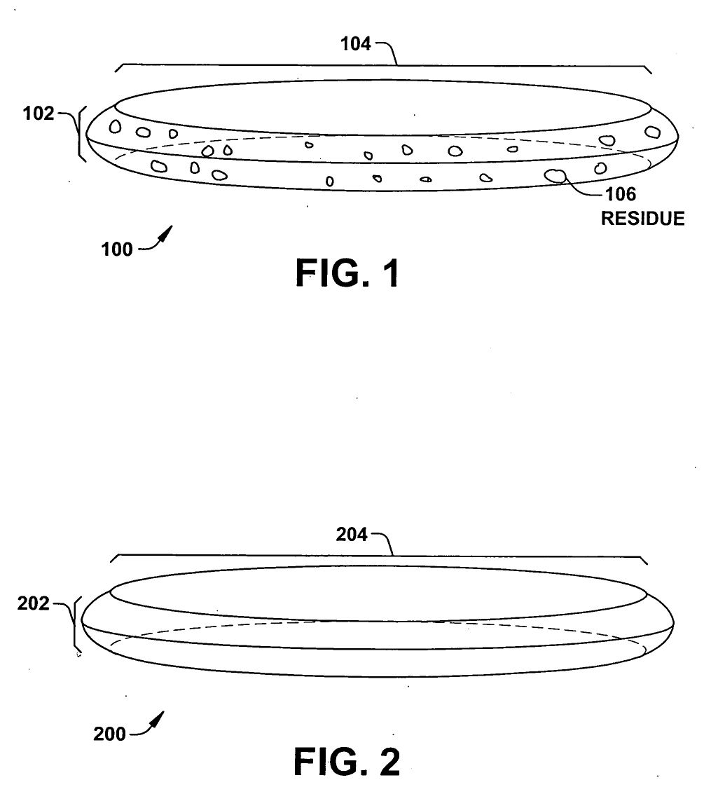

FIG. 1 is a perspective view of an exemplary semiconductor wafer 100 with edge residue. The wafer 100 is comprised of a semiconductor material, such as silicon. The wafer 100 has an edge surface 102, a top surface 104, and a bottom surface (not referenced with a reference numeral).

The top surface 104 is generally where semiconductor devices, such as transistors, capacitors, memory arrays, logic, and the like are formed. The top surface 104 can comprise a number of individual dies that have semiconductor devices formed therein. The wafer 100 has different layers and components formed therein according to the semiconductor devices being formed thereon and also according to a stage of fabrication. For example, at an initial stage of fabrication, the top surface 104 merely comprises silicon. At later stages of fabrication, isolation layers, gate structures, source drain regions, metallization layers, and the like can be formed thereon.

The edge surface 102 has a relatively curved or beveled surface and does not typically have devices formed thereon. The edge surface can be employed to hold or secure the wafer 100 during fabrication processes.

The fabrication processes employed to form semiconductor devices on the top surface 104 produce unwanted residue 106, including debris and contaminants that can remain on the top surface 104 and the edge surface 102 of the wafer 100. For illustrative purposes, the residue 106 is depicted only on the edge surface 102. For example, chemical mechanical planarization is typically employed in device fabrication. This planarization employs a slurry that is typically cleaned from the top surface 104 by, for example, mechanical scrubbing devices. However, despite cleaning processes, some slurry can remain on the edge surface 102 and the top surface 104. Other sources of residue include metallization processes, which can leave metal materials as residue and debris. Additionally, patterning processes employ photoresist, which may not be completely removed and also becomes a source of residue. Still other sources of residue include, wafer holding mechanisms, such as pedestals, cassettes, and the like, which are often comprised at least partly of carbon material. In one example, wafer holding mechanisms grab and/or support wafers on their edges. As a result, the wafer holding mechanisms can leave carbon residue on the wafer edges. Another example of residue is fluorine, which can be introduced by fabrication processes that employ fluorine.

The residue 106 can be troublesome to remove and/or prevent from contaminating subsequent processes. Conventional cleans can fail to remove substantial portions of residue from the edge surface and can risk damaging devices formed on the wafers. The residue, including debris and/or contaminants, can relocate from the edge surface 102 and onto or about the top surface 104. Subsequently performed fabrication processes and structures can be degraded due to the presence of the residue 106. For example, layers can be formed on the residues or contaminants leading to blistering, delamination, undesired voids, and the like.

In one example, residue can be present on the edge surface 102. A pre-metal deposition liner is formed over the wafer 100 and covers or encapsulates the residue. Subsequently, a pre-metal layer is formed on the liner. However, the residue encapsulated in the liner can eject or explode from the liner, particularly when heated, and relocate to other rejoins of the device. The residue may be ejected due at least in part to compositions of the residue and the liner. The residue, once ejected from the liner, can relocate to other areas or regions of the wafer and impair device operation. The residue can result in undesired shorting, undesired open circuits, and the like and diminish yield.

FIG. 2 is a perspective view of another exemplary semiconductor wafer 200 wherein edge residue has been removed. The wafer 200 is comprised of a semiconductor material, such as silicon. The wafer 200 has an edge surface 202, a top surface 204, and a bottom surface (not shown).

The top surface 204 is generally where semiconductor devices, such as transistors, capacitors, memory arrays, logic, and the like are formed. The top surface 204 can comprise a number of individual dies that have semiconductor devices formed therein. The wafer 200 has different layers and components formed therein according to the semiconductor devices being formed thereon and also according to a stage of fabrication. The edge surface 202 has a relatively curved surface and does not have devices formed thereon. The edge surface is often employed to hold or secure the wafer 200 during fabrication processes.

The wafer 200, in this example, is shown without residue on the edge surfaces 202 of the wafer 200. The residue may have been present as shown in FIG. 1, but removed via an aspect of the invention. As a result, performance of devices formed on the wafer 200 is not substantially degraded by residue, as may happen with the device in FIG. 1.

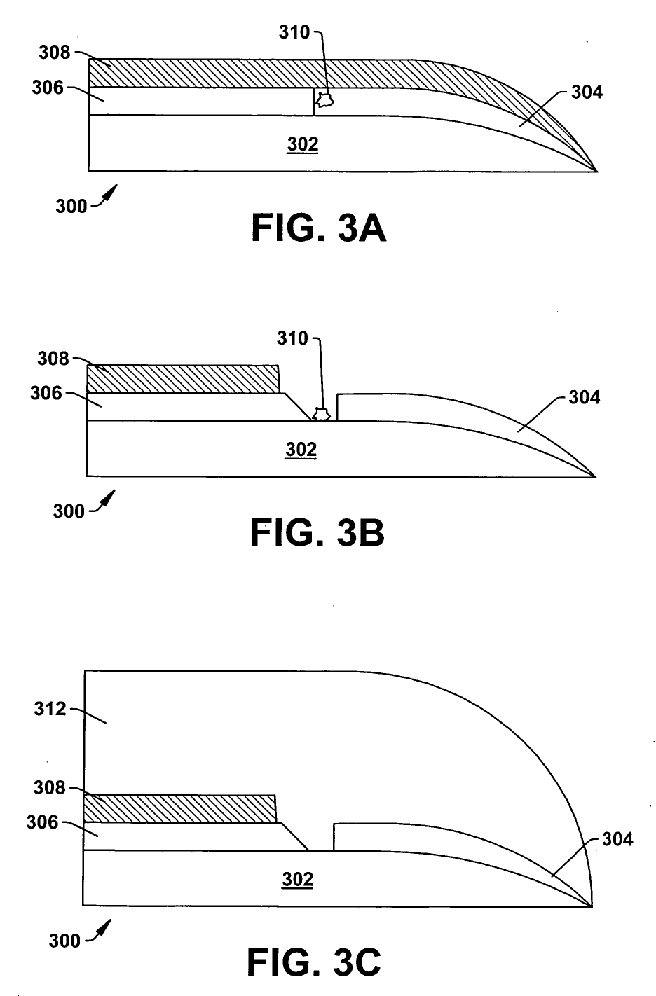

FIGS. 3A to 3C depict a portion of a wafer 300 at an edge surface wherein edge residue is removed and/or contained in accordance with an aspect of the invention. The FIGS. 3A to 3C are presented as examples in order to illustrate residue removal and/or containment. It is noted that aspects of the invention can operate on wafers having layers and structures varied from that shown in FIGS. 3A to 3C.

FIG. 3A is a cross sectional view of the wafer 300 at an edge surface in accordance with an aspect of the invention. The wafer 300 includes a semiconductor substrate or body 302 comprised of a semiconductor material such as silicon. The wafer 300 includes an edge surface that extends a radial distance, such as about 0.1 mm to about 0.5 mm, from an outer edge of the wafer 300. An oxide layer 304 is shown formed near an edge of the wafer 300.

In one example, the oxide layer 304 is a shallow trench isolation oxide or other isolation structure. A silicide region 306 is shown formed on the semiconductor body 302. The sulicide region 306 is comprised of a suitable conductive material, such as TiSi₂, CoSi₂, or NiSi, however other compositions can employed. A liner 308 is formed on the silicide region 306 and the oxide layer 304. The liner 308, in one example, is comprised of silicon nitride and is a pre-metal dielectric liner.

A defect or residue 310 is present and is encapsulated by the liner 308. Without removal and/or containment, the defect 310 can migrate and damage devices formed elsewhere on the wafer 300.

FIG. 3B is another cross sectional view of the wafer 300 in accordance with an aspect of the invention. FIG. 3B illustrates the wafer 300 after an edge portion of the liner 308 has been removed. As a result, the defect 310 is now exposed.

A suitable wash and/or etch process can be employed to remove the edge portion of the liner 308. In one example, a backside wash employing hydro fluoric acid is employed. Additionally, portions of the oxide layer 304 and the silicide region 306 can also be removed.

FIG. 3C is yet another cross sectional view of the wafer 300 in accordance with an aspect of the invention. FIG. 3C illustrates the wafer 300 after formation of an insulative layer 312 wherein the defect 310 is contained and/or removed from the edge surface. The insulative layer 312 is formed on/over the oxide layer 304 and the liner 306. The insulative layer 312 can be a poly metal dielectric (PMD) layer comprised of a suitable dielectric material. In one example, the insulative layer 312 is comprised of phosphosilicate glass (PSG). The PSG, like many dielectric/insulative materials, is typically formed by a high density plasma process that includes simultaneous etching and deposition components.

The formation of the insulative layer 312 causes the defect 310 to evaporate and/or become contained or benign. The formation of the insulative layer 312 employs a suitable temperature, plasma formation properties, and duration during the formation process that causes the defect 310 to dissipate or, alternately, to be prevented from relocating to other parts of the wafer 300.

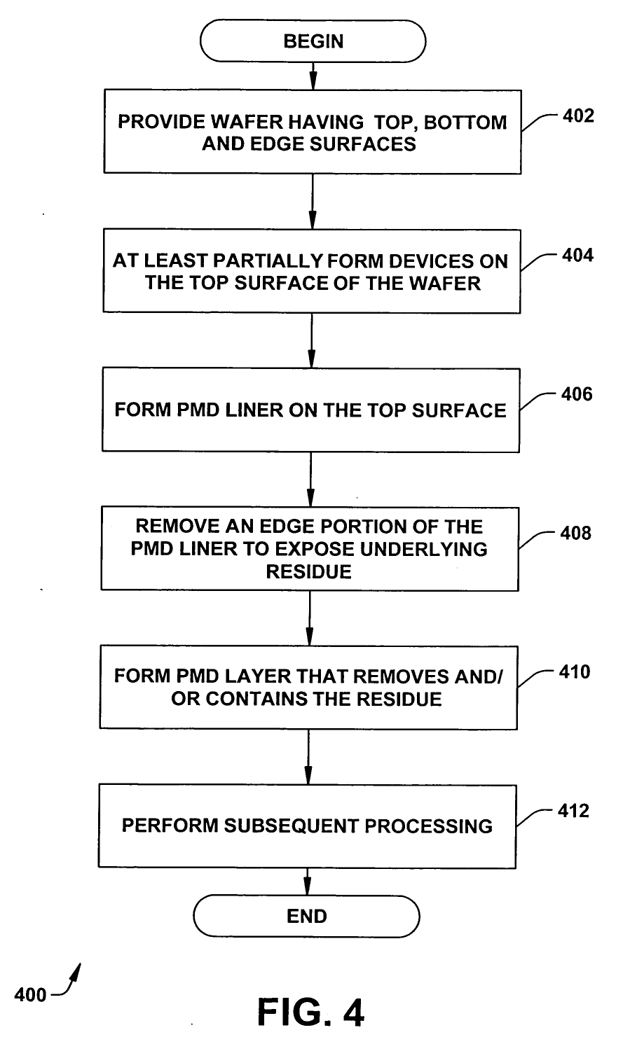

FIG. 4 is a flow diagram illustrating a method 400 of fabricating a semiconductor device wherein edge residue is removed and/or contained in accordance with an aspect of the invention. While the method 400 is illustrated and described as a series of acts or events, it will be appreciated that the present invention is not limited by the illustrated ordering of such acts or events. For example, some acts may occur in different orders and/or concurrently with other acts or events apart from those illustrated and/or described herein, in accordance with the invention. In addition, not all illustrated steps may be required to implement a methodology in accordance with the present invention.

The method 400 begins at block 402, wherein a wafer comprised of a semiconductor material and having a top surface, a bottom surface and an edge surface is provided. The top surface and the bottom surface are substantially planar and on opposite surfaces of the wafer. The edge surface is non planar and may have a parabolic profile. Additionally, the edge surface is located on an outer edge of the wafer.

Transistor devices are at least partially formed on the semiconductor wafer at block 404 by performing a series of fabrication processes that form source/drain regions, gate structures, isolation regions, and the like on the top surface of the wafer. In one example, devices are formed up to about 2.7 mm form an outer edge of the wafer. The transistor devices can include n-type and/or p-type transistor devices. Additionally, silicide regions can be formed on the source/drain regions and on the gate structures in order to reduce contact resistance and facilitate operation of the fabricated devices. Edge residue, such as carbon particles, can be formed on the edge surfaces as a byproduct of the fabrication processes performed at block 404. In particular, silicide formation processes, such as silicide strip, can generate the edge residue.

A pre-metal dielectric liner or capping liner is formed over the top surface of the wafer at block 406 by depositing and/or forming a suitable liner material such as nitride. The pre-metal dielectric liner mitigates undesired dopant diffusion to later formed layers and facilitates subsequent formation of a pre-metal dielectric layer. The liner can encapsulate the edge residue. Other compositions and/or types of liner or layers can be employed.

An example of a suitable process for forming a liner is provided. A plasma enhanced chemical vapor deposition (PECVD) process is performed to deposit a silicon nitride layer over the transistors, where the layer has an as-deposited hydrogen content of about 20 atomic percent or more, and where the nitride can provide an initial tensile stress of about 400-500 MPa in at least a portion of the NMOS channel region of the semiconductor body. As a result, the liner is comprised of silicon nitride and is more etchable in HF than other silicon nitride layers. In another example, an exemplary PECVD process is performed at about 350 degrees Celsius or less, with a deposition chamber pressure of about 3.5 Torr or more, a silane (SiH4) gas flow of about 150 sccm or less, and an ammonia (NH3) gas flow of about 2500-3000 sccm, using high frequency RF power of about 50 W at 13.56 MHz, and low frequency power of about 10-20 W at 350 KHz. The liner has a relatively fast etch rate in HF since it is not densified as deposited. It is meta-stable with a relatively high hydrogen content and can impart a moderate tensile stress in all or a portion of the NMOS channel region of the substrate after the deposition process, such that subsequent application of thermal energy during back-end processing causes a reduction in the hydrogen content and an increase in the applied tensile stress in the NMOS channel region. It is noted that the liner can, for example, be formed so as to be relatively more etchable by a selected etch chemistry.

The nitride layer may be formed to any suitable thickness, such as about 300 Å or more, about 500 Å in one example.

A wafer wash or clean process can optionally be performed prior to forming the pre-metal dielectric liner in alternate aspects. As an example, a clean with hydro-fluoric acid and/or sulfuric acid can be applied to the edge surfaces of the wafer. However, such processes may not remove sufficient amounts of residue in order to limit degradation of the devices formed on the wafer due to the residue.

An edge portion of the pre-metal dielectric liner is selectively removed at or the edge surface of the wafer at block 408 to expose the residue. Some underlying residue may be removed during this process. The size or radial distance of the edge portion removed, defined inwardly from the outer edge of the wafer, can be selected so as to avoid damaging structures. For example, the radial distance of the edge portion removed can be about 0.1 mm to about 2.50 mm. A suitable mechanical and/or chemical wash process or etch process can be employed to remove the edge portion. In one example, a solution comprising hydrofluoric acid is selectively applied from the back surface to the edge surface of the wafer in order to remove the edge portion of the pre-metal dielectric liner. The removal process can also mitigate removal of backside films, such as oxide, silicon nitride, and the like, which may be present on the bottom surface of the wafer. Backside films can be present to, for example, alter stress, seal the bottom surface of the wafer, and the like.

An example of suitable process parameters for a wraparound etch/clean to remove the edge portion is shown below. A suitable solution has a chemical concentration comprised of 4.9 percent Hydrofluoric acid (HF). The solution is flowed at a rate of 1.00 lpm. During the wraparound etch/clean process, the wafer is spun at about 1400 rpm. After a period of time, a water rinse is performed with the wafer spun at about 500 rpm. Subsequently, a dry operation is performed with nitrogen gas while the wafer is spun at about 2000 rpm.

In another example of removing the edge portion, a “sacrificial” photoresist coat is formed over the wafer and exposed only the edge. The wafer is then sent to plasma etch for a dry etch process, removing the nitride liner. The photoresist is then removed. It is noted that the other suitable processes can be employed to remove edge portions of the liner in accordance with aspects of the present invention.

A clean/etch solution can be applied to the edge surface of the wafer in order to remove the edge portion of the pre-metal dielectric liner in a number of suitable manners. For example, the solution can be directionally applied to only the wafers edge while the wafer itself is rotated. As another example, the solution can be applied to a bottom surface of a wafer and permitted to wrap around to the edge surface. In another example, the solution can be applied to a top surface of a wafer and permitted to wrap around the edge surface from the top surface.

It is noted that alternate aspects of the invention can include removing the residue as part of the edge portion removal process.

Subsequently, a pre-metal dielectric layer is formed on the pre-metal dielectric liner at block 410 that contains and/or removes the residue. The formation of the pre-metal dielectric layer is performed with a suitable temperature, plasma, and/or other parameters that cause the residue, which has been exposed, to dissipate or be contained. For example, thermal energy can cause the residue to form into volatile compounds that are then exhausted or evaporated away from the wafer. Additionally, the formation process can stabilize the residue and prevent relocation of the residue to other parts of the wafer and formed devices thereon. Furthermore, the formation process can mechanically and/or directly remove the residue.

Some examples of suitable temperatures for the formation process include about 450 degrees Celsius or more. However, it is appreciated that temperatures below 450 degrees Celsius may also be employed and still remove the residue.

In one example, a high density plasma (HDP) chemical vapor deposition (CVD) process is performed to form a pre-metal dielectric layer on the pre-metal dielectric liner. The thickness of the PMD layer is typically thicker than that of the PMD liner. Some examples of suitable thicknesses for the PMD layer include about 2,500 to about 12,000 Angstroms.

An example of a suitable PMD layer formation process follows. An initial preheat in Ar plasma with 120 sccm of argon is performed, where approximately 4.5 KW is applied to the dome, forming an inductively coupled plasma. The wafers are heated for approximately 60 s and during this time, energy from the plasma is used to heat the wafers to approximately 450 C. After a threshold temperature near 450 C is reached the plasma power is decreased to 3.75 KW, the argon gas is turned off and SiH4 and O2 gas are turned on, with flows of approximately 88 and 235 sccm, respectively, and 2.25 KW of high frequency power is applied to the electrostatic chuck. This high frequency power creates a bias which produces a favorable deposition condition, that adequate encapsulates structures formed on the wafer with the phosphorous-doped oxide. Phosphine diluted in SiH4 is also supplied during this deposition step and this serves to “dope” the oxide film with phosphorous to approximately 5 wt % phosphorous. To help regulate the wafer temperature, while contacting the electrostatic chuck (ESC), approximately 3.3 sccm of helium fluid is supplied to the back of the wafer and the a voltage is applied to the ESC to “clamp” the wafer. Typical deposition time is approximately 90 s for 9000 Angstroms of film. This above example is provided as an example to facilitate a better understanding of the present invention and is not intended to limit the invention to a particular PMD formation process. Alternate PMD layer formation processes that contain and/or remove residue are contemplated.

Thereafter, additional fabrication processing is performed at block 412 including, but not limited to, contact and via formation, metal layer formation, and the like.

It is noted that variations in the method 400 are contemplated and in accordance with the present invention. For example, it is appreciated that aspects of the invention can be applied to layers other than PMD liners and layers in order to remove and/or contain residue.

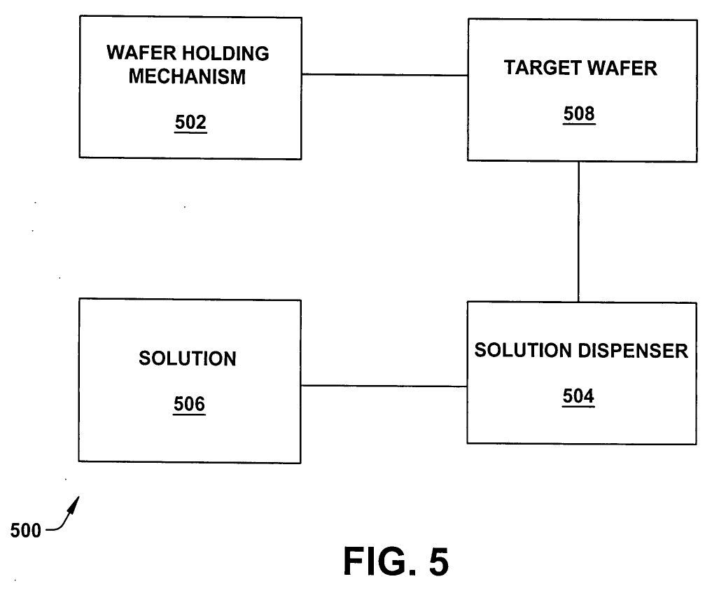

FIG. 5 is a block diagram illustrating a system 500 for removing and/or containing wafer edge residue in accordance with an aspect of the present invention. The system 500 applies a solution to wafer edge surfaces that removes a portion of a liner from the edge surfaces and expose underlying residue. The system 500 is described at a high level in order to facilitate understanding of the present invention.

The system 500 comprises a wafer holding mechanism 502, a solution dispenser 504, a residue remover solution 506, and operates on a target wafer 508. The wafer holding mechanism 502 can be in a variety of forms, shapes, sizes, and compositions in order to safely and securely hold the target wafer 508 during residue removal. In one example, the wafer holding mechanism comprises a series of prongs that come in contact with the top or bottom surface of the wafer and hold the wafer 508 in place. The wafer holding mechanism 502 is comprised of a material, such as silicon carbide, that mitigates contamination of the target wafer 508. The wafer holding mechanism 502 is typically designed/configured so that damage to formed devices on the top surface of the target wafer 508 is mitigated. For example, fingers and or suction can be employed by the wafer holding mechanism 502 to hold the top and/or bottom surfaces of the target wafer 508. Additionally, the wafer holding mechanism 502 can be configured to hold the wafer 508 only on the bottom surface, thereby further mitigating damage and/or contamination by the holder 502 to the top surface of the wafer 508.

The target wafer 508 is comprised of a semiconductor material, such as silicon, and has the top surface, bottom surface, and edge surface, as described above. A liner, such as a PMD liner, is formed over the top surface and portions of the edge surface of the target wafer 508. Other layers and/or structures can also be formed on the target wafer 508 including a liner. The edge surface can have residue attached thereto and encapsulated by the liner. Some possible sources of residue include carbon based materials, such as poly-tetra-fluoro-ethylene (PTFE), poly-flourinated-acitate (PFA), poly-vinyl-di-flouride (PVDF), and the like.

The solution dispenser 504 applies the solution 506 to the edge surface of the target wafer 508. The solution dispenser 504, in one example, comprises nozzles and connections thereto from a reservoir (not shown) that stores the solution 506. The solution dispenser 504 controls a number of parameters employed in dispensing the solution 506 including, but not limited, initial dispersion point, flow rate, solution composition, duration, temperature, and the like. The solution dispenser 504 can selectively apply the solution to selected/targeted portions of the wafer 508, including only the wafer edge surface, the wafer edge surface and the top surface, the wafer edge surface and the bottom surface, and the like. The solution dispenser 504 can, in an alternate aspect, cover or immerse the wafer 508 in the solution 506.

The solution 506 comprises an etch chemistry, a dissolving/cleaning chemistry, and/or a combination thereof. The etch chemistry or cleaning chemistry removes the strongly adhered residue from the wafer edge surfaces without substantially impacting or altering the top surface of the wafer 508.

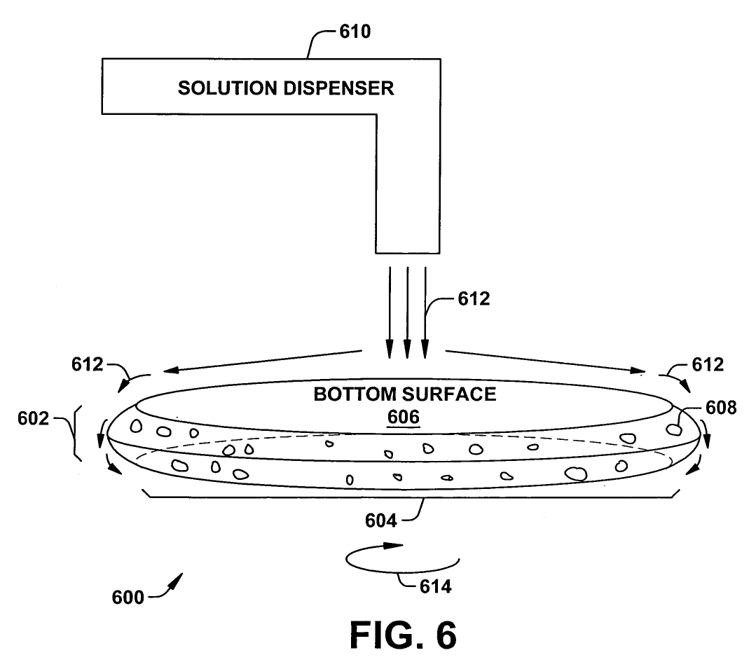

Turning now to FIG. 6, a view illustrating a solution dispenser 610 within a system that directs a solution toward a bottom surface 606 of a wafer 600 in accordance with an aspect of the present invention is provided. The view describes an example of a suitable solution dispenser for aspects of the invention, however it is appreciated that the present invention is not limited to this particular solution dispenser and includes other suitable solution dispensers and variations thereof that apply/provide residue remover solution to edge/bevel portions of target wafers.

The target wafer 600 is shown that has an edge surface 602, a top surface 604, and a bottom surface 606 and is comprised of a semiconductor material, such as silicon. The edge surface 602 is non-planar and may be parabolic. The edge surface 602 is located at an outermost edge of the wafer 600 and has residue 608 attached thereto. A top surface 604 is partially hidden and generally comprises partially formed semiconductor devices thereon. This top surface 604 is sensitive to solutions such as the solution 612 because such solutions can damaged the structures and layers formed thereon. The top surface 604 is substantially planar. A liner, such as a PMD liner, is formed on the top surface 604 and at least a portion of the edge surface 602 and encapsulates the residue 608. The bottom surface 606 does not typically have semiconductor devices formed thereon and is typically a planar surface of semiconductor material. The bottom surface 606, unlike the top surface 604, may not be as sensitive to cleaning/etching solutions, such as the solution 612, as there are typically no structures and/or layers that can be damaged.

The solution dispenser 610 obtains the solution 612 from a reservoir or other solution source (not shown). The solution dispenser 610 is located above the wafer 600 and directs the solution 612 towards a central portion of the bottom surface 606. The solution 612 flows from the central portion toward edges of the wafer 600 and eventually wraps around the edge portion 602 as shown in FIG. 6. At the same time, an inert gas, such as nitrogen, is typically sprayed onto the top surface 604 to mitigate or block flow of the solution 612 to the top surface 604. The solution dispenser 610 can adjust an amount of overage, which is the radial distance from the outer edge toward a central portion of the top surface, by adjusting parameters including, but not limited to, flow rate, solution composition, duration, rotational speed of the wafer 600, and the like. Generally, the solution dispenser 610 controls the parameters such that most of the edge surface 602 is in contact with the solution 612 without a substantial portion of the top surface 604 being in contact with the solution 612.

As a result of being in contact with the edge surface 602, the solution 612 removes an edge portion of the liner and exposes the residue 608. Subsequently, other processing can be performed to contain and/or remove the residue 608.

Although the invention has been illustrated and described with respect to one or more implementations, equivalent alterations and modifications will occur to others skilled in the art upon the reading and understanding of this specification and the annexed drawings. In particular regard to the various functions performed by the above described components (assemblies, devices, circuits, systems, etc.), the terms (including a reference to a “means”) used to describe such components are intended to correspond, unless otherwise indicated, to any component which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising.”

What is claimed is:

1. A method for containing or removing residue comprising:
providing a wafer comprised of a semiconductor material having a top surface, a bottom surface and an edge surface, wherein the bottom surface and the top surface are substantially planar, the edge surface is non-planar, and residue is located on the edge surface.
forming a liner over the top surface of the wafer and covering at least a portion of the residue; and
removing an edge portion of the liner to expose the portion of the residue.

2. The method of claim 1, further comprising removing the exposed residue by a thermal process.

3. The method of claim 2, wherein the thermal process is at a temperature of about 400 or more degrees Celsius.

4. The method of claim 1, further comprising forming a dielectric layer over the top surface of the wafer.

5. The method of claim 1, wherein forming the dielectric layer further comprises removing the portion of the residue.

6. The method of claim 1, wherein forming the dielectric layer further comprises causing the residue to become benign.

7. The method of claim 1, wherein forming the liner comprises depositing silicon-nitride as a capping liner.

8. The method of claim 6, wherein the silicon-nitride is etchable with hydrofluoric acid.

9. The method of claim 1, wherein removing the edge portion of the liner comprises employing a chemical mechanism.

10. The method of claim 1, wherein removing the edge portion of the liner comprises employing a chemical mechanism to applying a solution to edge surfaces of the wafer.

11. The method of claim 10, wherein the solution comprises hydrofluoric acid.

12. The method of claim 10, wherein the solution comprises hydrofluoric acid in an organic solution.

13. The method of claim 10, wherein the solution comprises sulfuric acid.

14. The method of claim 1, wherein the residue comprises carbon and fluorine.

15. A method for containing or removing residue comprising:
providing a wafer comprised of a semiconductor material having a top surface, a bottom surface and an edge surface, wherein the bottom surface and the top surface are substantially planar, the edge surface is non-planar, and residue is located on the edge surface;
forming a pre-metal dielectric liner over the top surface of the wafer and covering at least a portion of the residue; and
etching an edge portion of the liner to expose the portion of the residue; and
forming a pre-metal dielectric layer over the top surface of the wafer and the pre-metal dielectric liner.

16. The method of claim 15, further comprising forming one or more transistor devices on the top surface of the wafer.

17. The method of claim 16, further comprising forming suicide regions on the top surface of the wafer.

18. The method of claim 17, wherein etching the edge portion of the liner comprises selectively etching a radial distance from an outer edge of the wafer and selecting the radial distance that prevents exposing the formed silicide regions.

19. The method of claim 15, wherein the pre-metal dielectric liner comprises silicon-nitride and the pre-metal dielectric layer comprises phosphor-silicate glass.

20. The method of claim 15, wherein etching the edge portion of the pre-metal dielectric liner comprises selectively applying hydro-fluoric acid a radial distance from an outer edge of the wafer towards the top surface.

21. A system for containing and/or removing wafer edge residue comprising:
a wafer comprised of semiconductor material having a planar top surface, a bottom surface and an edge surface, wherein residue located on the edge surface, wherein a liner covers at least a portion of the top surface and at least a portion of the edge surface;
a holding mechanism that holds the wafer; and
a solution dispenser that dispenses a solution on the edge surface, wherein the solution selectively removes an edge portion of the liner from at least a portion of the edge surface and exposes the underlying residue.

22. The system of claim 1, wherein the solution dispenser dispenses the solution on only the edge surface.

23. The system of claim 1, wherein the solution dispenser dispenses the solution on the bottom surface and the edge surface.
